(19) United States
(12) Patent Application Publication
(10) Pub. No.: US 2023/0095537 A1
(43) Pub. Date: Mar. 30, 2023

(54) SYSTEM, SUBSTRATE PROCESSING APPARATUS, AND METHOD OF MANUFACTURING SEMICONDUCTOR DEVICE

(71) Applicant: KOKUSAI ELECTRIC CORPORATION, Tokyo (JP)

(72) Inventors: Ryosuke TAKAHASHI, Toyama (JP); Masakazu SAKATA, Toyama (JP); Masamichi YACHI, Toyama (JP); Masamichi SAKASHITA, Toyama (JP)

(73) Assignee: KOKUSAI ELECTRIC CORPORATION, Tokyo (JP)

(21) Appl. No.: 17/888,831

(22) Filed: Aug. 16, 2022

(30) Foreign Application Priority Data
Sep. 24, 2021 (JP) 2021-156139

(51) Int. Cl. C23C 16/44; C23C 16/455; C23C 16/458; H01L 21/67

(52) U.S. Cl. CPC C23C 16/4412; C23C 16/45519; C23C 16/4588; C23C 16/4586; H01L 21/67248

(57) ABSTRACT

There is provided a technique that includes: an exhauster including a casing in which a rotating body is installed; a gas supplier configured to supply an inert gas to the exhauster without passing through a process chamber; and a controller configured to be capable of controlling the gas supplier to supply the inert gas into the casing based on a temperature drop of the rotating body expected in advance in a state where a processing object is not being processed in the process chamber such that a temperature of the rotating body becomes equal to or higher than a target temperature.

### CROSS-REFERENCE TO RELATED APPLICATION

This application is based upon and claims the benefit of priority from Japanese Patent Application No. 2021-156139, filed on Sep. 24, 2021, the entire contents of which are incorporated herein by reference.

### TECHNICAL FIELD

The present disclosure relates to a system, a substrate processing apparatus, and a method of manufacturing a semiconductor device.

### BACKGROUND

With the increase in the amount of a precursor gas used in a film-forming process of a substrate processing apparatus in recent years, due to the increase in the amount of gas exposure inside a pump, the adhesion of by-products has become remarkable, which makes it necessary to control the internal temperature of the pump to a temperature at which no reaction occurs. When the substrate processing apparatus becomes in a standby state, since the flow rate of a gas flowing into the pump decreases and the internal temperature of the pump is lowered, a warm-up operation may be required to raise the internal temperature of the pump before starting the next process.

### SUMMARY

Some embodiments of the present disclosure aim at suppressing the adhesion of by-products inside a pump.

According to embodiments of the present disclosure, there is provided a technique that includes: an exhauster including a casing in which a rotating body is installed; a gas supplier configured to supply an inert gas to the exhauster without passing through a process chamber; and a controller configured to be capable of controlling the gas supplier to supply the inert gas into the casing based on a temperature drop of the rotating body expected in advance in a state where a processing object is not being processed in the process chamber such that a temperature of the rotating body becomes equal to or higher than a target temperature.

### BRIEF DESCRIPTION OF DRAWINGS

The accompanying drawings, which are incorporated in and constitute a part of the specification, illustrate embodiments of the present disclosure.

FIG. 1 is a top view showing an example of a substrate processing apparatus according to embodiments of the present disclosure.

FIG. 2 is a longitudinal sectional view showing an example of a substrate processing apparatus according to the embodiments of the present disclosure, as viewed from a front side.

FIG. 3A is a longitudinal sectional view showing an example of a process furnace according to embodiments of the present disclosure.

FIG. 3B is a view showing a portion of a gas supplier.

FIG. 4 is a longitudinal sectional view showing an example of a booster pump according to embodiments of the present disclosure.

FIG. 5 is a graph showing a relationship between a process and a time of a substrate processing apparatus according to embodiments of the present disclosure.

FIG. 6 is a schematic diagram for explaining a concept of a temperature control operation of a substrate processing apparatus according to embodiments of the present disclosure.

FIG. 7 is a graph showing a relationship between a gas supply amount and a rotor temperature of a substrate processing apparatus according to embodiments of the present disclosure.

FIG. 8 is a graph showing a relationship between a flow rate of a gas supplied to the booster pump and a rotor temperature.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A substrate processing apparatus 1 as an example of a system according to embodiments of the present disclosure will be described with reference to the drawings. The drawings used in the following description are all schematic, and the dimensional relationship, ratios, and the like of various elements shown in figures do not always match the actual ones. Further, the dimensional relationship, ratios, and the like of various elements between plural figures do not always match each other.

Hereinafter, non-limiting examples of the present disclosure will be described. Throughout the drawings, the same or corresponding configurations are denoted by the same or corresponding reference numerals, and explanation thereof will not be repeated. Further, the side of a storage chamber 13 to be described later is referred to as a front side (an anterior front side), and the side of a first utility system 54A and a second utility system 54B, which will be described later, is referred to as a rear side (a posterior side). Further, a side facing a boundary line (an adjoining surface) of a first process module 2A and a second process module 2B, which will be described later, is referred to as an inner side, and a side away from the boundary line is referred to as an outer side.

In the present embodiments, the substrate processing apparatus is configured as a vertical substrate processing apparatus (hereinafter referred to as a substrate processing apparatus) 1 that carries out a substrate processing process such as heat treatment, as a manufacturing process in a method of manufacturing a semiconductor device.

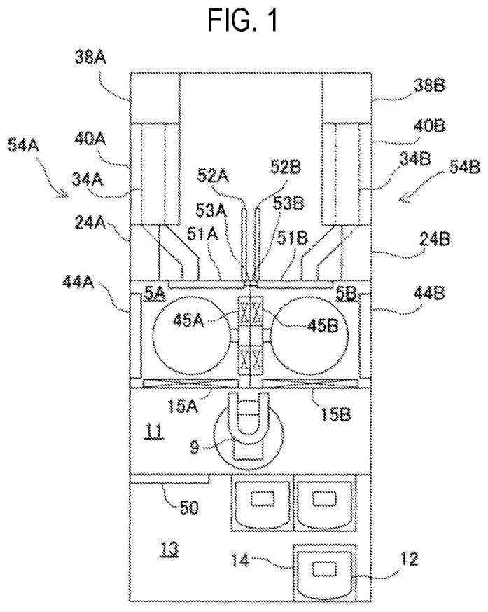

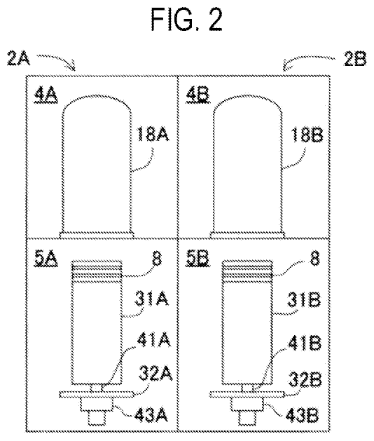

As shown in FIGS. 1 and 2, the substrate processing apparatus 1 includes a first process module 2A and a second process module 2B. The process modules 2A and 2B includes a housing or a framework, which has substantially a rectangular parallelepiped contour, and one side surfaces thereof are arranged in close contact with or adjoined to each other in parallel. The process module 2A is composed of a first process furnace 4A (a process furnace 4A) and a first transfer chamber 5A (a transfer chamber 5A). The process module 2B is composed of a second process furnace 4B (a process furnace 4B) and a second transfer chamber 5B (a transfer chamber 5B).

The transfer chamber 5A and the transfer chamber 5B are arranged below the process furnace 4A and the process furnace 4B, respectively. A transfer chamber 11 is arranged adjacent to the front side of the transfer chamber 5A and the transfer chamber 5B. The transfer chamber 11 includes a housing having substantially a rectangular parallelepiped outer shape and is provided with a transfer device 9 that transfers a wafer 8. A storage chamber 13 for storing a pod (FOUP (Front Opening Unified Pod)) 12 for storing a plurality of wafers 8 is connected to the front side of the transfer chamber 11. The storage chamber 13, the process modules 2A and 2B, and the transfer chamber 11 have an outer diameter based on a polyhedron composed of planes, which are orthogonal to each other, and are configured to be detachable, and their connection portions have appropriate airtightness. An I/O port 14 is installed on the front surface of the storage chamber 13, and the pod 12 is loaded/unloaded into/out of the substrate processing apparatus 1 via the I/O port 14.

A first gate valve 15A (a gate valve 15A) and a second gate valve 15B (a gate valve 15B), which are configured to transfer a substrate between the transfer chambers 5A and 5B and the transfer chamber 11, are installed at a boundary wall (an adjacent surface) of the transfer chambers 5A and 5B and the transfer chamber 11, respectively. A clean unit 17, which is configured to supply clean air to the transfer chamber 11, is installed on the ceiling of the transfer chamber 11 and is configured to circulate the clean air, for example, an inert gas, in the transfer chamber 11. By circulating and purging the transfer chamber 11 with the inert gas, it is possible to make the transfer chamber 11 to be a clean atmosphere.

Since the process module 2A and the process module 2B have substantially the same (plane symmetric) configuration except for details, only the process module 2A will be described below as a representative.

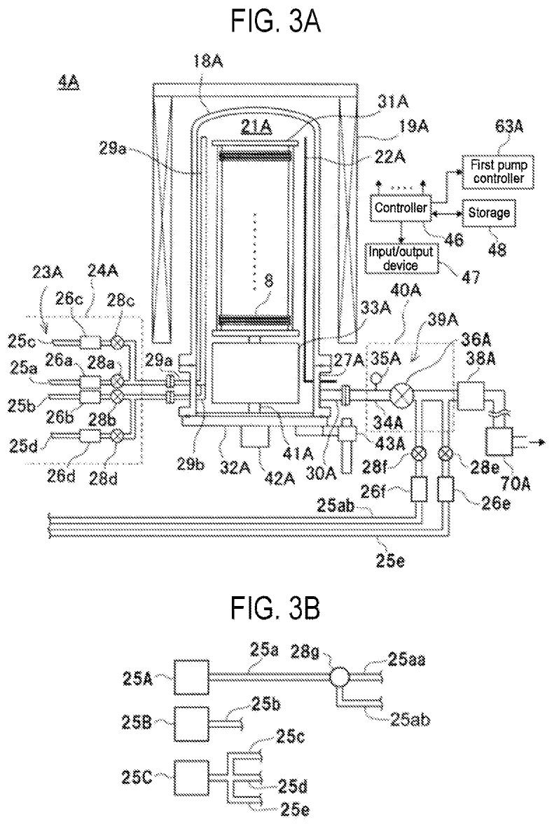

As shown in FIGS. 3A and 3B, the process furnace 4A includes a cylindrical first process container 18A (a reaction tube 18A) and a first heater 19A (a heater 19A) as a heating means (a heating mechanism) installed on the outer periphery of the reaction tube 18A. The reaction tube 18A is formed of, for example, quartz (Si) or silicon carbide (SiC). A first process chamber 21A (a process chamber 21A) for processing the wafer 8 as a substrate is formed inside the reaction tube 18A. Further, a first temperature detector 22A as a temperature detector is installed to be erected in the reaction tube 18A along the inner wall of the reaction tube 18A.

A gas used for substrate processing is supplied to the process chamber 21A by a first gas supply mechanism 23A as a gas supply system. The gas supplied by the gas supply mechanism 23A may be changed according to the type of a film to be formed. Here, the gas supply mechanism 23A includes a precursor gas supplier, a reaction gas supplier, and an inert gas supplier. The gas supply mechanism 23A is accommodated in a first supply box 24A (a gas box) to be described later.

The precursor gas supplier includes a precursor gas tank 25A, and a gas supply pipe 25a is connected to the precursor gas tank 25A. The gas supply pipe 25a is connected to a first gas supply pipe 25aa and a second gas supply pipe 25ab via a switching valve 28g.

The first gas supply pipe 25aa is provided with a mass flow controller (MFC) 26a, which is a flow rate controller (a flow rate control part), and a valve 28a which is an opening/closing valve sequentially from the upstream direction. The first gas supply pipe 25aa is connected to a nozzle 29a that penetrates the side wall of a first manifold 27A (a manifold 27A). The nozzle 29a is installed to be erected in the reaction tube 18A along a vertical direction, and is formed with a plurality of supply holes opened toward the wafer 8 held by a first boat 31A (a boat 31A). A precursor gas is supplied to the wafer 8 through the supply holes of the nozzle 29a.

The second gas supply pipe 25ab is provided with a mass flow controller (MFC) 26f and a valve 28f that is an opening/closing valve. The second gas supply pipe 25ab is connected to an exhaust pipe 34A between a first conductance-variable valve 36A and a first booster pump 38A, which will be described later.

Hereinafter, in the same configuration, the reaction gas supplier includes a reaction gas tank 25B, and a reaction gas is supplied from the reaction gas tank 25B to the wafer 8 via a gas supply pipe 25b, an MFC 26b, a valve 28b, and a nozzle 29b. The inert gas supplier includes an inert gas tank 25C, and an inert gas is supplied from the inert gas tank 25C to the wafer 8 via gas supply pipes 25c and 25d, MFCs 26c and 26d, valves 28c and 28d, and the nozzles 29a and 29b.

Further, it is able to supply the inert gas from the inert gas tank 25C to the exhaust pipe 34A, which will be described later, via a gas supply pipe 25e, an MFC 26e, and a valve 28e.

The cylindrical manifold 27A is connected to the lower end opening portion of the reaction tube 18A via a sealing member such as an O-ring to support the lower end of the reaction tube 18A. The lower end opening portion of the manifold 27A is arranged to correspond to the ceiling of the transfer chamber 5A and is opened/closed by a disc-shaped first lid 32A (a lid 32A). A sealing member such as an O-ring is installed on the upper surface of the lid 32A, whereby the reaction tube 18A and the outside air are air-tightly sealed. A first heat insulator 33A (a heat insulator 33A) is placed on the lid 32A.

A first exhaust port 30A (an exhaust port 30A), which extends in a direction orthogonal to the center of axis, that is, a direction orthogonal to the tube axis of the reaction tube 18A, is formed in the manifold 27A, and the first exhaust pipe 34A is attached to the manifold 27A via the exhaust port 30A.

A first booster pump 38A as an example of the exhauster is connected to the exhaust pipe 34A via a first pressure sensor 35A (a pressure sensor 35A) as a pressure detector (a pressure detection part) for detecting the pressure of the process chamber 21A and a first conductance-variable valve 36A as a pressure adjustment valve (pressure adjustment part). It is possible to adjust the flow rate of a gas discharged from the process chamber 21A by adjusting the first conductance-variable valve 36A.

The gas supply pipe 25e for supplying an inert gas from the inert gas supplier is connected to the exhaust pipe 34A between the first conductance-variable valve 36A and the first booster pump 38A.

A main pump 70A is connected to the first booster pump 38A on the downstream side in an exhaust direction. A vacuum pump such as a dry pump is used for the main pump 70A.

Further, the booster pump 38A improves an exhaust speed of the main pump 70A in a pressure region (for example, 1 Pa to 1 kPa) where the exhaust speed decreases. Since the exhaust speed is determined by the rotation speed of a rotor as a rotating body except for the vicinity of the ultimate vacuum degree, the variation in the exhaust speed is reduced as compared with a case where only the main pump 70A is used. As the booster pump 38A, various mechanical booster pumps such as a rotary blade type (axial flow type), a screw type, and a scroll type may be used in addition to a roots type, and further, all kinds of pumps having a compressive action, such as a turbo molecular pump and an ejector, may be used.

The conductance-variable valve 36A is configured to include an APC (Auto Pressure Controller) valve for pressure adjustment. An exhaust system 39A as a first exhaust system is mainly composed of the exhaust pipe 34A, the pressure sensor 35A, and the conductance-variable valve 36A. The exhaust system 39A may be accommodated in a first exhaust box 40A (an exhaust box 40A) to be described later.

The boat 31A as a substrate holder that vertically supports a plurality of wafers 8, for example, 10 to 150 wafers 8, in a shelf shape is accommodated in the process chamber. The boat 31A is supported above the heat insulator 33A by a first rotary shaft 41A (a rotary shaft 41A) that penetrates the lid 32A and the heat insulator 33A. The rotary shaft 41A is connected to a first rotation mechanism 42A (a rotation mechanism 42A) installed below the lid 32A. The rotary shaft 41A is configured to be rotatable in a state of air-tightly sealing the interior of the reaction tube 18A. The lid 32A is driven in the vertical direction by a first boat elevator 43A (a boat elevator 43A) as an elevating mechanism. As a result, the boat 31A and the lid 32A are integrally raised and lowered, and the boat 31A is loaded/unloaded into/from the reaction tube 18A.

As shown in FIG. 3A, the substrate processing apparatus 1 includes a controller 46. The rotation mechanism 42A, the boat elevator 43A, the MFCs 26a to 26f, the valves 28a to 28f, the switching valve 28g, the conductance-variable valve 36A, the pressure sensor 35A, a first pump controller 63A (see FIG. 1) and the like shown in FIG. 3A are connected to the controller 46 that controls them.

### (Controller)

The controller 46 is composed of, for example, a microprocessor (a computer) including a CPU and is configured to be capable of controlling the operation of the process modules 2A and 2B. An input/output device 47 configured as, for example, a touch panel or the like, is connected to the controller 46. One controller 46 may be installed in each of the process module 2A and the process module 2B, or one controller 46 may be installed in common thereto.

A storage 48 as a storage medium is connected to the controller 46. The storage 48 readably stores a control program for controlling the operation of the substrate processing apparatus 1 and a program (also referred to as a recipe) for causing each component of the substrate processing apparatus 1 to perform a process according to the process conditions.

The storage 48 may be a storage device (a hard disk or a flash memory) built in the controller 46, or may be a portable external storage device (a magnetic tape, a magnetic disk such as a flexible disk or a hard disk, an optical disc such as a CD or a DVD, a magneto-optical disc such as an MO, or a semiconductor memory such as a USB memory or a memory card). Further, the programs may be provided to the computer by using a communication means such as the Internet or a dedicated line. The programs are read from the storage 48 according to an instruction or the like from the input/output device 47 as necessary and the controller 46 executes a process according to the read recipe, whereby the substrate processing apparatus 1 performs a desired process under control of the controller 46. The controller 46 is accommodated in a control box (not shown) provided at an arbitrary location in the substrate processing apparatus 1.

Next, the rear surface configuration of the substrate processing apparatus 1 will be described.

### (Utility System)

A first utility system 54A (a utility system 54A) and a second utility system 54B (a utility system 54B), which extends rearward, are installed close to the rear surfaces of the process modules 2A and 2B. The utility systems 54A and 54B are arranged in plane symmetry so as to face each other via a maintenance area. The utility systems 54A and 54B include the supply boxes 24A and 24B, the exhaust boxes 40A and 40B, and the booster pumps 38A and 38B, respectively. The maintenance opening of each box of the utility systems 54A and 54B is formed inside (maintenance area side).

Since the utility systems 54A and 54B have substantially the same configuration except for details, only the utility system 54A will be described below as a representative. The supply box 24A is arranged adjacent to the outer side portion of the rear surface of the transfer chamber 5A. The exhaust box 40A is arranged adjacent to the outer side portion of the rear surface of the process furnace 4A.

### (Booster Pump 38A)

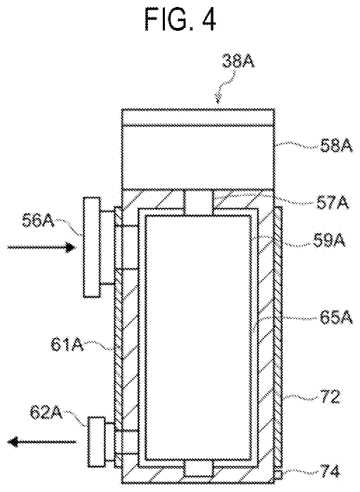

Next, the booster pump 38A will be described with reference to FIG. 4. The booster pump 38A in this embodiment is configured to be installed vertically. By installing it vertically, it makes the footprint (the installation area) small. The booster pump 38B has the same configuration as the booster pump 38A.

The booster pump 38A is composed of a main body (casing) 61A having an internal space (a rotor chamber), one or more rotors 59A rotating in the main body 61A, an intake port 56A connected to the exhaust pipe 34A and provided at the upper side surface of the main body 61A, a first exhaust port 62A provided at the lower side surface of the main body 61A for exhausting a gas, a motor 58A for rotating a rotary shaft 57A of the rotor 59A, a first pump controller 63A for controlling the motor 58A, and ancillary equipment (not shown) for supplying a ballast gas, cooling water, etc. The first pump controller 63A is connected to the controller 46 (see FIG. 3A).

A first gas flow path 65A (a gas flow path 65A) is formed in the booster pump 38A by the inside of the intake port 56A, the inside of the exhaust port 62A, and an intermediate chamber moving between the main body 61A and the rotor 59A.

A gas introduced from the intake port 56A flows through the gas flow path 65A and is discharged from the exhaust port 62A. The intake port 56A opens orthogonal to the rotary shaft 57A so as to directly face the rotor chamber, and the exhaust port 62A opens on the same side surface with the intake port 56A or an opposite side surface of the intake port 56A, and is connected to the intake port of the main pump 70A (not shown in FIG. 4, see FIGS. 3A and 3B) via a pipe (not shown in FIG. 4, see FIGS. 3A and 3B).

Since the rotary shaft 57A is arranged to extend in the vertical direction, the main body 61A is vertically long. The main body 61A is made of cast iron and has a large weight. By installing the motor 58A on the main body 61A, the center of gravity of the booster pump 38A can be lowered as much as possible, so that the booster pump 38A can be stably installed.

As shown in FIG. 4, an electric heater 72 for heating the main body 61A and a temperature sensor 74 for detecting the temperature of the main body 61A are installed on the outer surface of the main body 61A of the booster pump 38A. As an example, the electric heater 72 is installed so as to cover the outer peripheral surface of the main body 61A which makes it possible to indirectly heat the rotor 59A through the main body 61A. The electric heater 72 and the temperature sensor 74 are connected to the controller 46.

The rotor 59A driven by the rotary shaft 57A is of a two-stage roots type including a plurality of rotors, for example, two rotors. A gas sucked from the intake port 56A through the exhaust pipe 34A is introduced into the exhaust port 62A while rotating in the gas flow path 65A with the rotation of the rotor 59A.

Here, the intake port 56A is installed on the upper side surface of the main body 61A, and the exhaust port 30A and the intake port 56A have the same or substantially the same height. Therefore, since the shape of the exhaust pipe 34A can be made in a straight line and horizontally arranged, a distance between the exhaust port 30A and the intake port 56A can be minimized, so that the exhaust capacity of the booster pump 38A can be fully utilized.

On the other hand, by installing the exhaust port 62A at the lower portion of the main body 61A, for example, it is possible to shorten the routing of pipes (not shown) up to the main pump 70A installed on the lower floor.

Next, the outline of a process of forming a film on the substrate (a film-forming process) will be described. Here, an example of forming a film on the wafer 8 by supplying a precursor gas and a reaction gas to the wafer 8 will be described. In the following description, the operation of each part constituting the substrate processing apparatus 1 is controlled by the controller 46 based on a program for executing a process recipe.

### (Wafer Charging and Boat Loading)

The gate valve 15A is opened to transfer the wafer 8 to the boat 31A. When a plurality of wafers 8 are charged into the boat 31A (wafer charging), the gate valve 15A is closed. The boat 31A is loaded into the process chamber 21A by the boat elevator 43A (boat loading), and the lower opening of the reaction tube 18A is hermetically closed (sealed) by the lid 32A.

### (Pressure Adjustment and Temperature Adjustment)

The process chamber 21A is vacuum-exhausted (decompression-exhausted) by the booster pump 38A and the main pump 70A so that the process chamber 21A has a predetermined pressure (vacuum degree). The atmosphere (air) of the process chamber 21A flows in a straight line or substantially in a straight line in the exhaust pipe 34 and is exhausted through the booster pump 38A and the main pump 70A. The pressure of the process chamber 21A is measured by the pressure sensor 35A, and the conductance-variable valve 36A is feedback-controlled based on the measured pressure information. Further, the reaction tube 18A is heated by the heater 19A so that the wafer 8 of the process chamber 21A has a predetermined temperature. At this time, the state of supplying electric power to the heater 19A is feedback-controlled based on the temperature information detected by the temperature detector 22A so that the process chamber 21A has a predetermined temperature distribution. Further, the rotation mechanism 42A starts the rotation of the boat 31A and the wafer 8.

### (Film-Forming Process)

### [Precursor Gas Supplying Step]

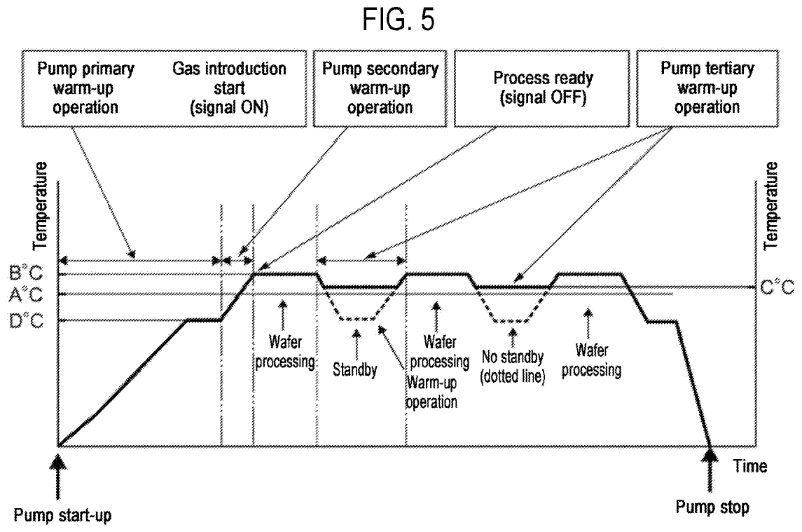

When the temperature of the process chamber 21A stabilizes at a preset processing temperature (for example, B degrees C. shown in FIG. 5 to be described later), a precursor gas is supplied to the wafer 8 in the process chamber 21A. The precursor gas is controlled by the MFC 26a so as to have a desired flow rate and is supplied to the process chamber 21A via the gas supply pipe 25a, the first gas supply pipe 25aa, and the nozzle 29a.

Examples of the precursor gas may include inorganic-based halosilane precursor gases such as an MCS (SiH₃Cl: monochlorosilane) gas, a DCS (SiH₂C₂: dichlorosilane) gas, a TCS (SiHCl₃: trichlorosilane) gas, and an HCD (Si₂Cl₆: hexachlorodisilane) gas, amino-based (amine-based) silane precursor gases that do not contain a halogen group, such as a 3DMAS (Si[N(CH₃)₂]₃H: trisdimethylaminosilane) gas and a BTBAS (SiH₂[NH(C₄H₉)]₂: vistert-butylaminosilane) gas, and inorganic-based silane precursor gases that do not contain a halogen group, such as an MS (SiH₄: monosilane) gas and a DS (Si₂H₆: disilane) gas.

### [Precursor Gas-Exhausting Step]

Next, the supply of the precursor gas is stopped, and the process chamber 21A is vacuum-exhausted by the booster pump 38A and the main pump 70A. The precursor gas in the process chamber 21A flows in a straight line or a substantially straight line in the exhaust pipe 34A and is exhausted via the booster pump 38A and the main pump 70A. At this time, an inert gas may be supplied from the inert gas supplier to the process chamber 21A (inert gas purging).

Examples of the inert gas may include rare gases such as a nitrogen (N₂) gas, an argon (Ar) gas, a helium (He) gas, a neon (Ne) gas, a xenon (Xe) gas, and the like. One or more of these gases may be used as the inert gas. This point equally applies to each step to be described later.

### [Reaction Gas-Supplying Step]

Next, a reaction gas is supplied to the wafer 8 in the process chamber 21A. The reaction gas is controlled by the MFC 26b so as to have a desired flow rate and is supplied to the process chamber 21A via the gas supply pipe 25b and the nozzle 29b.

As the reaction gas, for example, an oxidizing gas may be used. Examples of the oxidizing gas may include oxygen (O)-containing gases such as an oxygen (O₂) gas, an ozone (O₃) gas, a plasma-excited O₂ (O₂*) gas, an O₂ gas+hydrogen (H₂) gas, water vapor (H₂O gas), a hydrogen peroxide (H₂O₂) gas, a nitrous (N₂O) gas, a nitrogen monoxide (NO) gas, a nitrogen dioxide (NO₂) gas, a carbon monoxide (CO) gas, and a carbon dioxide (CO₂) gas. One or more of these gases may be used as the oxidizing gas.

### [Reaction Gas-Exhausting Step]

Next, the supply of the reaction gas is stopped, and the process chamber 21A is vacuum-exhausted by the booster pump 38A and the main pump 70A. The reaction gas in the process chamber 21A flows in a straight line or a substantially straight line in the exhaust pipe 34A and is exhausted via the booster pump 38A and the main pump 70A. At this time, an inert gas may be supplied from the inert gas supplier to the process chamber 21A (inert gas purging).

By performing a cycle of performing the above-described four steps a predetermined number of times (one or more times), a film having a predetermined composition and a predetermined thickness can be formed on the wafer 8.

### (Boat Unloading and Wafer Discharging)

After forming the film on the wafer 8, an inert gas is supplied from the inert gas supplier, so that the atmosphere of the process chamber 21A is replaced with the inert gas and the pressure of the process chamber 21A is returned to the normal pressure. After that, the lid 32A is lowered by the boat elevator 43A, and the boat 31A is unloaded from the reaction tube 18A (boat unloading). After that, the processed wafer 8 is discharged from the boat 31A (wafer discharging).

After that, the wafer 8 may be accommodated in the pod 12 and unloaded out of the substrate processing apparatus 1, or may be transferred to the process furnace 4B in which the substrate processing such as annealing may be continuously performed. When the wafer 8 is continuously processed in the process furnace 4B after the wafer 8 is processed in the process furnace 4A, the gate valve 15A and the second gate valve 15B are opened and the wafer 8 is directly transferred from the boats 31A to a second boat 31B (a boat 31B). The subsequent loading/unloading of the wafer 8 into/from the process furnace 4B is performed in the same procedure as in the substrate processing by the process furnace 4A described above. Further, the substrate processing in the process furnace 4B is performed, for example, by the same procedure as the substrate processing in the process furnace 4A described above.

Examples of the process conditions for forming a film on the wafer 8 are described as follows: processing temperature (wafer temperature): 300 degrees C. to 700 degrees C., processing pressure (process chamber pressure): 1 Pa to 4,000 Pa, precursor gas: 100 sccm to 10000 sccm, reaction gas (oxidizing gas): 100 sccm to 10,000 sccm, inert gas: 100 sccm to 10,000 sccm. By setting the processing conditions to values within the respective ranges, the film-forming process can be appropriately advanced.

### (Warm-Up Operation of Booster Pump)

By the way, when the booster pump 38A is driven to introduce a gas into the booster pump 38A, the gas is compressed in the booster pump 38A to generate compression heat, so that the temperature of the booster pump 38A rises. On the other hand, not only if the booster pump 38A is stopped for a long time for maintenance, but also if the flow rate of a flowing gas is low even when the booster pump 38A is driven, no compression heat is generated, so that the internal temperature of the pump drops. When the temperature of the pump drops, the booster pump 38A performs a warm-up operation, but the warm-up operation is a time-consuming task, which is one of factors for lowering the operating rate of the apparatus.

Further, when a processing gas (for example, the precursor gas or the reaction gas) is exhausted by the booster pump 38A while the temperature is lowered, there may a case that by-products (for example, a SiO film) adhere to the cooled rotor 59A (in some cases, inside the main body 61A in contact with the processing gas), which causes the drive of the booster pump 38A to be hindered, in other words, there may a case that the predetermined performance of the booster pump 38A is not exhibited or the booster pump 38A is blocked.

Therefore, in the substrate processing apparatus 1 of the present embodiment, the following measures are taken so that the by-products do not adhere to the rotor 59A whose temperature is lowered due to maintenance or the like.

A graph shown in FIG. 5 shows the relationship between the device drive status of the booster pump 38A and the like and the time.

### (1) Booster Pump Primary Warm-Up Operation

Before the substrate processing apparatus 1 is first started after maintenance and the first wafer 8 is being processed, the heating of the main body 61A of the booster pump 38A by the electric heater 72 is started, and the booster pump 38A and the main pump 70A are driven while supplying an inert gas in the inert gas tank 25C to the exhaust pipe 34A via the gas supply pipe 25e, the MFC 26e, and the valve 28e to perform a primary warm-up operation of the booster pump 38A. When the inert gas is supplied to the exhaust pipe 34A via the gas supply pipe 25e, the MFC 26e, and the valve 28e, the conductance-variable valve 36A is closed.

In the primary warm-up operation, a compression heat is generated by compressing the inert gas with the booster pump 38A and exhausting it to the main pump 70A. Here, when the rotor of the booster pump 38A is rotated to compress and exhaust a sucked gas, the gas is compressed to generate the compression heat. Therefore, the rotor can be heated with the compression heat generated by compressing the gas. The gas introduced into the booster pump 38A without passing through the process chamber 21A may be the same type of gas as a gas for processing a processing object in the process chamber 21A, or may be a different gas. As an example, a case where the temperature of the rotor 59A of the booster pump 38A is maintained at a temperature (D degrees C.) slightly lower than a target temperature (A degrees C.) will be described below. In this case, as shown in FIG. 5, since the temperature rise due to the compression heat of the inert gas is insufficient, a difference (degrees C.) between the target temperature (A degrees C.) and the low temperature (D degrees C.) is calculated, and the flow rate of the inert gas is set to be higher such that the temperature can be raised by this difference. The target temperature (A degrees C.) described here is a temperature of the rotor 59A in which by-products do not adhere to the rotor 59A.

The calorific value of the compression heat can be increased or decreased by adjusting the supply amount of the inert gas supplied to the booster pump 38A with the MFC 26e. The supply amount of the inert gas is adjusted by controlling the MFC 26e with the controller 46. For example, when the supply amount of the inert gas supplied to the booster pump 38A increases, the calorific value of the compression heat increases, and when the supply amount of the inert gas decreases, the calorific value of the compression heat decreases.

In this primary warm-up operation, the supply amount of the inert gas to the booster pump 38A is generally set to be the same as the supply amount of a gas that contributes to the processing of the substrate during the film formation of the wafer 8. However, the supply amount of the inert gas to the booster pump 38A can be increased or decreased as needed.

### (3) Booster Pump Secondary Warm-Up Operation

In the secondary warm-up operation, the inert gas is supplied to the booster pump 38A at a flow rate for raising the temperature greater than the calculated temperature difference between the target temperature (A degrees C.) and the low temperature (D degrees C.). By heating the inert gas with the compression heat, the temperature of the rotor 59A of the booster pump 38A can reach a temperature (B degrees C.) higher than the target temperature (A degrees C.). In this way, in the secondary warm-up operation, the controller 46 can bring the temperature of the rotor 59A of the booster pump 38A to the temperature (B degrees C.) higher than the target temperature (A degrees C.).

In the warm-up operations, the temperature of the rotor 69A is raised not only by heating the electric heater 72 but also by an assist from the compression heat of the inert gas, but the flow rate of the inert gas that can be supplied at one time is limited. Therefore, as described above, the flow rate of the inert gas is adjusted to the steady-state supply amount of the gas that contributes to the processing of the substrate during the film formation of the wafer 8. Therefore, in case that the target temperature (A degrees C.) (desirably the temperature (B degrees C.)) is reached by an assist of the temperature rise due to the compression heat in the steady-state supply amount, there is not needed to perform two-step warm-up operations as in the present embodiment.

Further, after the temperature of the rotor 59A of the booster pump 38A reaches the temperature (B degrees C.) by controlling the MFC 26e so as to adjust the supply amount of the inert gas, the MFC 26f may be controlled to supply the precursor gas. For example, the valve 28e of the gas supply pipe 25e is closed to stop the supply of the inert gas to the exhaust pipe 34A. Subsequently, the precursor gas of the precursor gas tank 25A is supplied to the exhaust pipe 34A via the gas supply pipe 25a, the switching valve 28g, the second gas supply pipe 25ab, the MFC 26f, and the valve 28f, and the booster pump 38A compresses the precursor gas and is heated by the compression heat of the precursor gas. Therefore, the rotor 59A is maintained at a high temperature (B degrees C.).

### (4) Process (Substrate Processing) State

In the secondary warm-up operation, since the temperature of the rotor 59A of the booster pump 38A reaches the temperature (B degrees C.) higher than the target temperature (A degrees C.), the booster pump 38A is ready to receive the precursor gas in the substrate processing such that by-products do not adhere to the rotor 59A. Therefore, the switching valve 28g can be switched to supply the precursor gas to the wafer 8 in the process chamber 21A to perform the precursor gas supply step described above.

Further, in the process chamber 21A, the reaction gas supply step and the reaction gas exhaust step are continuously performed, and the flow rate of the gas contributing to the processing of the substrate is controlled in each step. For example, the precursor gas after processing the wafer 8 in the process chamber 21A is exhausted to the booster pump 38A and the main pump 70A via the conductance-variable valve 36A that is an open state.

Here, the temperature of the rotor 59A of the booster pump 38A is held at the temperature (B degrees C.) higher than the target temperature (A degrees C.). For example, the controller 46 controls the MFC 26a and the first conductance-variable valve 36A to adjust the supply amount of the gas that contributes to the processing of the substrate in each step, including the precursor gas, to the booster pump 38A.

Further, the electric heater 72 is controlled by the controller 46 in the course of performing the precursor gas supply step, the reaction gas supply step, and the reaction gas exhaust step in the process chamber 21A.

### (5) Booster Pump Tertiary Warm-Up Operation

After the processing (process) of the wafer 8 is completed, the processed wafer 8 is taken out from the process chamber 21A, and a gas from the process chamber 21A is not introduced into the booster pump 38A in a standby state until the next unprocessed wafer 8 is loaded into the process chamber 21A.

In such a standby state, the flow rate of an exhausted gas is reduced and it is difficult to generate the compression heat, so that the temperature of the booster pump 38A gradually decreases. If the time taken until the processing of the next unprocessed wafer 8 starts is long, the temperature of the rotor 59A may be lower than the target temperature (A degrees C.), so that the warm-up operations described above have to be performed before the processing of the next wafer 8.

Therefore, in the present embodiment, the controller 46 predicts the point of time at which the temperature of the rotor 59A drops to the target temperature (A degrees C.), and controls each part such that the rotor 59A has a temperature (for example, C degrees C.<B degrees C.) slightly higher than the target temperature (A degrees C.) to supply the inert gas of the inert gas tank 25C to the exhaust pipe 34A via the gas supply pipe 25e, the MFC 26e, and the valve 28e and maintain the temperature of the rotor 59A of the booster pump 38A at the temperature (C degrees C.) slightly higher than the target temperature (A degrees C.) even during the standby state.

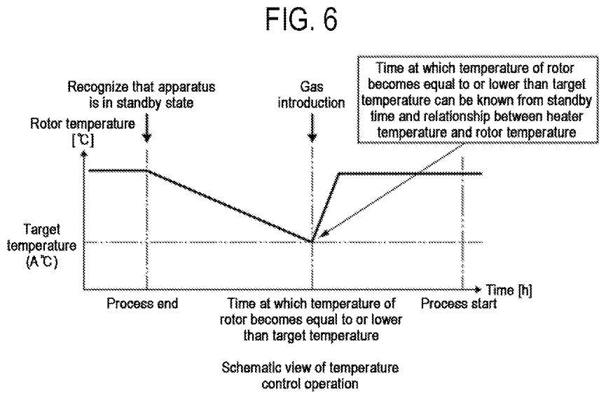

FIG. 6 shows the concept of predicting the time when the temperature of the rotor 59A becomes equal to or lower than the target temperature. As shown in FIG. 6, from the point of time that the apparatus is in the standby state after the processing (film-forming process) of the wafer 8 is completed, the exhauster is operating but an exhaust gas is reduced which results in not generating the compression heat, so that the temperature of the rotor 59A gradually decreases. The relationship between the temperature of the rotor 59A and the elapsed time is measured in advance by an experiment or the like and the relationship (table) between the temperature obtained by the experiment or the like and the time is stored in advance in the controller 46. Therefore, the controller 46 is capable of controlling each part such that the rotor 59A has the temperature slightly higher than the target temperature (A degrees C.) (for example, C degrees C.<B degrees C.). B degrees C. is also stored in advance in the controller 46.

Since the temperature of the rotor 59A is controlled by the controller 46 as described above, in the processing of the next wafer 8 and the subsequent processing of the wafer 8, it is possible to suppress the adhesion of by-products to the rotor 59A of the booster pump 38A, as in the case of the first processing of the wafer 8.

In case where it is needed to change the target temperature for preventing the by-product from the adhesion due to the change of the precursor gas or to change a heat-resistant temperature due to the change of the booster pump 38A, by changing values referred to from the table of the relationship between the standby time and the rotor temperature, it possible to flexibly cope with various changes.

Further, in the above embodiment, in the primary warm-up operation after maintenance, the supply amount of the inert gas to the booster pump 38A is set to be the same as the steady-state supply amount of the precursor gas in the course of the film formation of the wafer 8. However, in the primary warm-up operation, the supply amount of the inert gas to the booster pump 38A may be increased more than the steady-state supply amount of the precursor gas in the course of the film formation of the wafer 8.

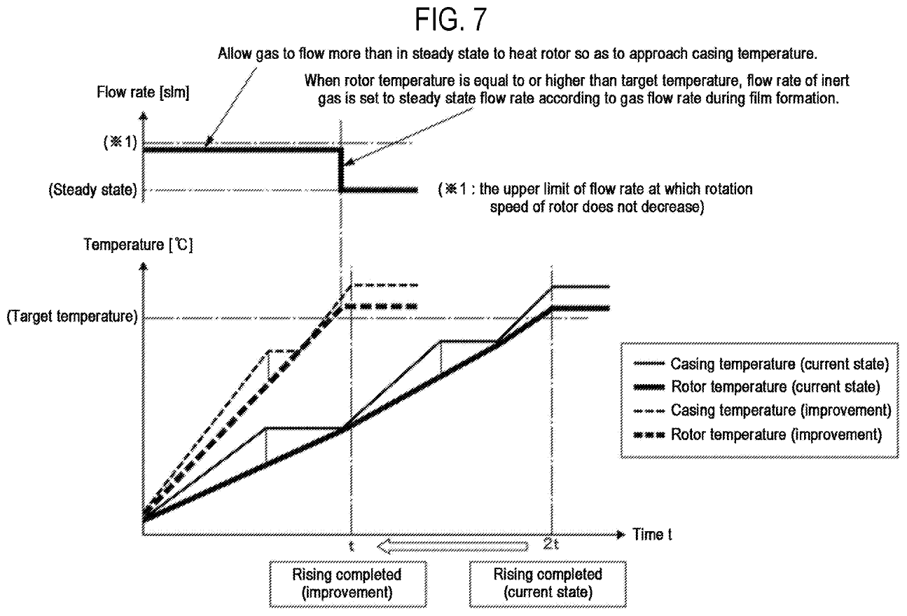

FIG. 7 shows a graph comparing the rotor temperature in a case where in the primary warm-up operation, the supply amount of the inert gas to the booster pump 38A is set to be the same as the steady-state supply amount in the course of the film formation of the wafer 8 with the rotor temperature in a case where the supply amount of the inert gas is increased more than the steady-state supply amount. In FIG. 7, the vertical axis represents the flow rate of the inert gas supplied to the booster pump 38A, and the horizontal axis represents the time.

As shown in FIG. 7, it can be seen that in the primary warm-up operation, the temperature of the rotor 59A of the booster pump 38A can be raised rapidly by increasing the supply amount of the inert gas to the booster pump 38A more than the steady-state supply amount in the course of the film formation of the wafer 8.

Further, when the inert gas is excessively supplied to the booster pump 38A, a large load is applied to the motor 58A that rotates the rotor 59A, and the rotation speed of the rotor 59A is lowered, which is not desirable. A one-dot chain line of 1 in FIG. 7 indicates the upper limit of the flow rate (supply amount) at which the rotation speed of the rotor 59A of the booster pump 38A does not decrease. When the supply amount of the inert gas is increased more than the steady-state supply amount, it is desirable to set the supply amount of the inert gas to the booster pump 38A so as to be less than the upper limit indicated by the one-dot chain line.

### (Heating of Main Body 61A of Booster Pump 38A by Electric Heater)

In the substrate processing apparatus 1 of the present embodiment, the main body 61A of the booster pump 38A can be heated by the electric heater 72. By heating the main body 61A, the heat of the main body 61A can be given to the rotor 59A installed inside the main body 61A, so that the temperature of the rotor 59A can be raised.

The controller 46 is capable of predicting a decrease in the temperature of the rotor 59A based on a set temperature of the electric heater 72, a temperature detection value from the temperature sensor 74 that measures the temperature of the main body 61A, and the relationship between the temperature of the rotor 59A and the time.

Therefore, the controller 46 is capable of heating the rotor by controlling the temperature of the electric heater 72 based on the prediction of the temperature drop of the rotor 59A such that the by-products do not adhere to the rotor 59A.

In the substrate processing apparatus 1 of the present embodiment, since the rotor 59A can be heated by the electric heater 72, the rotor 59A can be heated more quickly than in a case where the rotor 59A is heated only by the compression heat, so that the time required for the warm-up operations can be shortened.

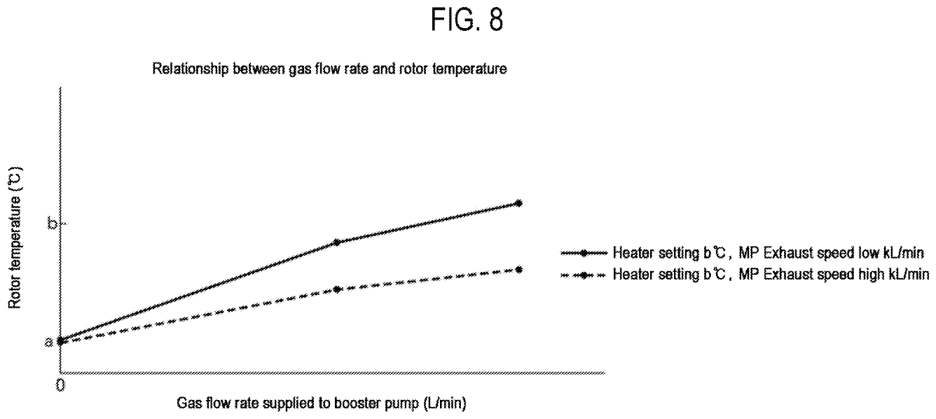

A graph shown in FIG. 8 shows the relationship between the set temperature of the electric heater 72, the temperature of the rotor 59A, and the exhaust speed of the main pump 70A. In FIG. 8, the vertical axis represents the temperature of the rotor 59A, and the horizontal axis represents the flow rate of a gas supplied to the booster pump 38A. Further, a graph line indicated by a solid line shows a case where the set temperature of the electric heater 72 is set to b degrees C. and the exhaust speed of the main pump 70A is set to be low, and a graph line indicated by a dotted line shows a case where the set temperature of the electric heater 72 is set to b degrees C. and the exhaust speed of the main pump 70A is set to be high.

From FIG. 8, it can be seen that even when the main body 61A of the booster pump 38A is heated to b degrees C. by the electric heater 72, if the supply amount of a gas supplied to the booster pump 38A is zero even when the booster pump 38A is driven, the temperature of the rotor 59A can only be raised to a degrees C., which is lower than b degrees C. This is because, as shown in FIG. 4, there is a gap between the main body 61A and the rotor 59A, and due to the structure of the booster pump 38A, the rotor 59A cannot be directly heated by the electric heater or the like.

Further, from FIG. 8, it can be seen that when the main body 61A is heated by the electric heater 72 and a gas is supplied to the booster pump 38A to drive the booster pump 38A, the compression heat is generated and the rotor temperature rises. It can also be seen that the rotor temperature rises by increasing the flow rate of the gas supplied to the booster pump 38A.

Further, when the booster pump 38A is driven, the main pump 70A is also driven, but in comparison between the case where the exhaust speed of the main pump 70A is low (the graph line indicated by the solid line) and the case where it is high (the graph line indicated by the dotted line), the rotor temperature is lower in the higher exhaust speed than in the lower exhaust speed. This is because when the exhaust speed of the main pump 70A on the exhaust side of the booster pump 38A increases, the compression amount of a gas of the booster pump 38A decreases so that the generation amount of the compression heat decreases. Therefore, it is desirable to balance the capacities of the booster pump 38A and the main pump 70A such that the rotor temperature becomes high.

According to the present embodiment, one or more of the following effects can be obtained.

(1) After processing the processing object, the controller is capable of controlling the gas supplier to supply a predetermined amount of gas into the casing while driving the electric heater and can set the temperature of the rotor to the target temperature or higher. Therefore, it is possible to prevent the by-products from adhering to the rotor. Therefore, since it is possible to prevent the by-products from adhering to the rotor, it is possible to suppress the blockage of the exhauster, thereby prolonging the maintenance cycle of the exhauster.

(2) The exhauster can perform the warm-up operation while supplying a gas that does not pass through the process chamber to the exhauster after maintenance or while waiting for the processing of the processing object.

(3) The pressure adjustment variable valve that adjusts the pressure of the process chamber is installed between the process chamber and the exhauster, and the controller is capable of controlling the gas supplier to stop the supply of a gas that does not pass through the process chamber when the variable valve is in an open state. When the gas used in the process chamber is exhausted, the gas passes through the pressure adjustment variable valve and is exhausted by the exhauster. While the exhauster is driven to exhaust the gas, the compression heat is generated and the rotor is heated, so that it is not necessary to supply the gas that does not pass through the process chamber, to the exhauster.

(4) The substrate processing apparatus 1 includes the process chamber in which the substrate is processed with a gas, the exhauster including the casing in which the rotor is installed and exhausting the gas used in the process chamber, the gas supplier that supplies a gas to the exhauster without passing the gas through the process chamber, and the controller that controls the gas supplier to supply a predetermined amount of gas into the casing while driving the electric heater after processing the substrate and sets the rotor temperature to the target temperature or higher. When the rotor is rotated in order to compress and exhaust a gas sucked into the exhauster, the gas is compressed to generate the compression heat. Therefore, the rotor can be heated by the compression heat generated by compressing the gas.

As a result, the controller controls the gas supplier to supply a predetermined amount of gas into the casing while driving the electric heater, so that the temperature of the rotor can be set to the target temperature or higher. Therefore, by-products can be prevented from adhering to the rotor. Since it is possible to prevent the by-products from adhering to the rotor, it is possible to suppress the blockage of the exhauster, thereby prolonging the maintenance cycle of the exhauster.

(5) The controller includes the exhauster and the gas supplier and is capable of controlling the gas supplier to supply a predetermined flow rate of gas into the casing of the exhauster without passing the gas through the process chamber such that the temperature of the rotor is equal to or higher than the target temperature. As a result, even when the processing gas is not supplied in the state of waiting for a long time and there is no substrate in the process chamber, the gas (for example, an inert gas) can be supplied by predicting the required compression heat of the gas in advance. As a result, the temperature of the rotor can be lowered to prevent the by-products from adhering to the rotor.

In this way, the exhauster can be operated while supplying a gas (for example, an inert gas) that does not pass through the process chamber, so that it is possible to suppress the adhesion of the by-products to the rotor, and thus the blockage of the exhauster and the like can be suppressed. As a result, the maintenance cycle of the exhauster can be lengthened.

### Other Embodiments

The embodiments of the present disclosure have been specifically described above. However, the present disclosure is not limited to the above-described embodiments, but various changes can be made without departing from the gist thereof.

The present disclosure is not limited to such embodiments, and the type of film formed on the wafer 8 is not limited. As an example of the film formed on the wafer 8, a SiO film can be mentioned. As an alternative or in addition to these, to these, a nitrogen (N)-containing gas (nitriding gas) such as an ammonia (NH₃) gas, a carbon (C)-containing gas such as a propylene (C₃H₆) gas, a boron (B)-containing gas such as a boron trichloride (BCl₃) gas, etc. can be used to form a SiN film, a SiON film, a SiOCN film, a SiOC film, a SiCN film, a SiBN film, a SiBCN film, and the like. Even when these film formations are performed, the film formation can be performed under the same process conditions as those in the above-described embodiments, and the same effects as those in the above-mentioned embodiments can be obtained.

Further, for example, the present disclosure can also be suitably applied to a case where a film containing a metal element such as titanium (Ti), zirconium (Zr), hafnium (Hf), tantalum (Ta), niobium (Nb), aluminum (Al), molybdenum (Mo), or tungsten (W), that is, a metal-based film, is formed on the wafer 8.

In the above-described embodiments, the example of depositing a film on the wafer 8 has been described, but the present disclosure is not limited to such embodiments. For example, the present disclosure can be suitably applied to a case where the wafer 8 or a film formed on the wafer 8 is subjected to a process such as an oxidation process, a diffusion process, an annealing process, or an etching process.

Further, the present disclosure can be applied not only to a semiconductor manufacturing apparatus but also to an apparatus for processing a glass substrate, such as an LCD apparatus, as a processing apparatus. Further, the film-forming process includes, for example, CVD, PVD, a process of forming, an oxide film, a nitride film, or both, a process of forming a film containing metal, and the like. Further, the process may be an annealing process, an oxidation process, a nitriding process, a diffusion process, or the like.

According to the present disclosure in some embodiments, it is possible to suppress the adhesion of by-products inside a pump.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A system comprising:
an exhauster including a casing in which a rotating body is installed;
a gas supplier configured to supply an inert gas to the exhauster without passing through a process chamber; and
a controller configured to be capable of controlling the gas supplier to supply the inert gas into the casing based on a temperature drop of the rotating body expected in advance in a state where a processing object is not being processed in the process chamber such that a temperature of the rotating body becomes equal to or higher than a target temperature.

2. The system of claim 1, wherein the controller determines a flow rate of the inert gas according to a flow rate of a gas supplied to the process chamber in a state where the processing object is being processed.

3. The system of claim 1, further comprising: a heater configured to heat the casing in which the rotating body is installed, from an outside of the casing,
wherein the controller is configured to be capable of predicting the temperature drop of the rotating body based on a set temperature of the heater, a temperature detection value from a temperature sensor installed in the casing, and a relationship between the temperature of the rotating body and a time.

4. The system of claim 3, wherein the relationship between the temperature of the rotating body and the time is maintained according to the set temperature of the heater.

5. The system of claim 1, further comprising: a valve configured to adjust a pressure of the process chamber,
wherein the controller stops the supply of the inert gas when the valve is operating.

6. The system of claim 5, further comprising: an exhaust pipe configured to exhaust a gas exhausted from the process chamber,
wherein the gas supplier is connected to the exhaust pipe at a downstream of the valve.

7. The system of claim 1, wherein the gas supplier is configured to supply a heated inert gas.

8. The system of claim 1, wherein the controller stops the supply of the inert gas in a state where the processing object is being processed in the process chamber.

9. The system of claim 1, wherein the controller is configured to compare the temperature of the rotating body in a state where the processing object is being processed with the target temperature, and
wherein the controller is configured not to supply the inert gas if the temperature of the rotating body is equal to or higher than the target temperature, and is configured to supply the inert gas if the temperature of the rotating body is lower than the target temperature.

10. The system of claim 1, wherein the controller is configured to supply the inert gas such that the temperature of the rotating body when the processing object becomes a state of being processed becomes equal to or higher than the target temperature.

11. The system of claim 1, wherein the controller is configured to supply the inert gas in a state where the temperature of the rotating body is higher than a predetermined temperature and the temperature of the rotating body decreases.

12. The system of claim 1, further comprising: a pump configured to exhaust a gas used in the process chamber,
wherein the exhauster is arranged between the process chamber and the pump, and
wherein the controller is configured to control the gas supplier to control a supply amount of the inert gas, based on an exhaust speed of the pump in a state where the processing object is not being processed.

13. The system of claim 1, wherein the inert gas is any one rare gas of a nitrogen gas, an argon gas, a helium gas, a neon gas, and a xenon gas.

14. A substrate processing apparatus comprising:
a process chamber in which a substrate is processed;
an exhauster including a casing in which a rotating body is installed;
a gas supplier configured to supply an inert gas to the exhauster without passing through the process chamber; and
a controller configured to be capable of controlling the gas supplier to supply the inert gas into the casing such that a temperature of the rotating body becomes equal to or higher than a target temperature, based on a temperature drop of the rotating body expected in advance in a state where the substrate is not being processed in the process chamber.

15. A method of manufacturing a semiconductor device, comprising:
processing a substrate; and
supplying, by a system comprising at least an exhauster including a casing in which a rotating body is installed and a gas supplier configured to supply an inert gas to the exhauster without passing through a process chamber, the inert gas into the casing such that a temperature of the rotating body becomes equal to or higher than a target temperature, based on a temperature drop of the rotating body expected in advance in a state where the substrate is not being processed in the process chamber.
